(19) United States
(12) Patent Application Publication
(10) Pub. No.: US 2011/0180208 A1
(43) Pub. Date: Jul. 28, 2011

(54) METHOD FOR LAMINATING PREPREG, METHOD FOR PRODUCING PRINTED WIRING BOARD AND PREPREG ROLL

(76) Inventors: Kenya TACHIBANA, Tokyo (JP); Kuniharu UMENO, Tokyo (JP); Kenichi KANEDA, Tokyo (JP)

(21) Appl. No.: 13/010,425

(22) Filed: Jan. 20, 2011

(30) Foreign Application Priority Data
Jan. 22, 2010 (JP) 2010-012442

(51) Int. Cl. H05K 3/00; B32B 37/02; B32B 37/06; B32B 37/10; B32B 37/14; C09J 7/02

(52) U.S. Cl. 156/285; 428/40.1

(57) ABSTRACT

A method for laminating a prepreg contributing to decrease in layer thickness and having high productivity, a method for producing a printed wiring board by the method for laminating the prepreg, and a prepreg roll used for the method for laminating the prepreg are provided. The method involves: 1) preparing a prepreg roll comprising a prepreg comprising at least a core layer, a first resin layer, a second resin layer, being thicker than the first resin layer, and a supporting base film which covers the first resin layer, wherein the prepreg with the supporting base film is rolled up into a roll; 2) unreeling the prepreg with the supporting base film from the prepreg roll, peeling off the peelable film if the second resin layer is covered with the peelable film, and layering the prepreg with the supporting base film on a circuit board so that the second resin layer side of the prepreg with the supporting base film faces a circuit of the circuit board; 3) vacuum laminating the prepreg; and 4) smoothing a surface of the first resin layer contacting the supporting base film by hot press.

### TECHNICAL FIELD

The present invention relates to a method for laminating a prepreg, a method for producing a printed wiring board and a prepreg roll.

### BACKGROUND ART

In recent years, with growing demand of higher function of electronics, high-density integration within electronic components and reduction in layer thickness have been demanded. Hence, in order to increase the density in printed wiring boards used for the electronic components, buildup multilayer printed wiring boards have been widely employed. The buildup multilayer printed wiring boards are generally produced by laminating insulating layers and conducting circuit layers, the insulating layer being constituted with a resin composition.

Patent Literature 1 discloses a prepreg comprising a core layer having a sheet-like base material, a first resin layer formed on one surface of the core layer and a second resin layer formed on the other surface of the core layer, wherein a first resin composition constituting the first resin layer is different from a second resin composition constituting the second resin layer and a conducting layer is formed on the first resin layer upon use. It is also disclosed in Patent Literature 1 that it is possible to arrange kinds and amounts of resins depending on properties required for each layer and the total thickness of the prepreg can be decreased while maintaining the properties required for each layer.

### CITATION LIST

### Patent Literature

[Patent Literature 1] Japanese Patent Application Laid-Open (JP-A) No. 2008-38066

### SUMMARY OF INVENTION

### Technical Problem

However, in the prepreg disclosed in Patent Literature 1, there is a difference in shrink characteristics between the first resin layer and the second resin layer since the thicknesses of the first resin layer and the second resin layer are different, so that the facing sides of the thicker resin layer curls inward to the middle of the resin layer, and it is difficult to handle such a prepreg. Therefore, the productivity of a printed wiring board produced using the prepreg decreases.

The present invention has been made in view of the above circumstances. Objects of the present invention are to provide a method for laminating a prepreg contributing to decrease in layer thickness and having high productivity, a method for producing a printed wiring board by the method for laminating the prepreg, and a prepreg roll used for the method for laminating the prepreg.

### Solution to Problem

The above objects can be attained by the following (1) to (7).

(1) A method for laminating a prepreg on a circuit board comprising the steps of:

1) preparing a prepreg roll selected from any of the following a) to c):

a) a prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the second resin layer side being disposed inside;

b) a prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the first resin layer side being disposed inside; and

c) a prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein the prepreg with the supporting base film is rolled up into a roll, the second resin layer side being disposed inside;

2) unreeling the prepreg with the supporting base film from the prepreg roll, peeling off the peelable film if the second resin layer is covered with the peelable film, and layering the prepreg with the supporting base film on a circuit board so that the second resin layer side of the prepreg with the supporting base film faces a circuit of the circuit board;

3) vacuum laminating the prepreg with the supporting base film on the circuit board by hot press from a supporting base film side of the prepreg with the supporting base film through a heat-resisting rubber; and

4) smoothing a surface of the first resin layer contacting the supporting base film by hot press from the supporting base film side of the prepreg with the supporting base film by means of a metal plate for press and/or metal roll for laminate.

(2) The method for laminating the prepreg according to the above (1) further comprising after the above step 4) of smoothing process:

5) sandwiching the circuit board having the prepreg with the supporting base film vacuum laminated between two SUS plates followed by curing at a temperature from 160 to 240° C. under ordinary pressure for 0.5 to 3 hours.

(3) The method for laminating the prepreg according to the above (1), wherein a thickness of the first resin layer is in the range from 0.5 to 20 μm, and a thickness of the second resin layer is in the range from 4 to 50 μm.

(4) A method for producing a printed wiring board, wherein an insulating layer on the printed wiring board is formed by the method for laminating a prepreg defined by any of the above (1) to (3).

(5) A prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the second resin layer side being disposed inside.

(6) A prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the first resin layer side being disposed inside.

(7) A prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein the prepreg with the supporting base film is rolled up into a roll, the second resin layer side being disposed inside.

### Advantageous Effects of Invention

According to the method for laminating the prepreg of the present invention, a printed wiring board contributing to decrease in layer thickness can be obtained with high productivity.

According to the method for producing a printed wiring board of the present invention, a printed wiring board contributing to decrease in layer thickness can be obtained with high productivity.

According to the prepreg roll of the present invention, a printed wiring board contributing to decrease in layer thickness can be obtained with high productivity.

### BRIEF DESCRIPTION OF DRAWINGS

FIG. 1A is a sectional view schematically showing a prepreg roll of a first embodiment of the present invention.

FIG. 1B is a sectional view schematically showing a prepreg roll of a second embodiment of the present invention.

FIG. 1C is a sectional view schematically showing a prepreg roll of a third embodiment of the present invention.

FIG. 2 is a sectional view schematically showing a state that a prepreg with a supporting base film is laminated on an inner circuit.

FIG. 3 is a sectional view schematically showing a state that a core layer is eccentrically located in the thickness direction of the prepreg with the supporting base film.

FIG. 4A is a schematical view of the prepreg roll of the first embodiment of the present invention set on a line of a lamination process.

FIG. 4B is a schematical view of the prepreg roll of the second embodiment of the present invention set on a line of a lamination process.

FIG. 4C is a schematical view of the prepreg roll of the third embodiment of the present invention set on aline of a lamination process.

FIG. 5 is a schematical view showing a curing process of a circuit board having the prepreg with the supporting base film vacuum laminated, sandwiched between SUS plates from both sides.

FIG. 6A is a photograph showing a prepreg with a supporting base film (after the prepreg with the supporting base film was layered on a circuit board, and before vacuum laminating) obtained in Example 1.

FIG. 6B is a photograph showing a prepreg with a supporting base film (after the prepreg with the supporting base film was layered on a circuit board, and before vacuum laminating) obtained in Comparative example 1.

### REFERENCE SIGNS LIST

1: Core layer
2: First resin layer
3: Second resin layer
31: End of second resin layer
4: Supporting base film
5: Peelable film
6: Inner circuit
61: End of inner circuit
7: Circuit board
8: Circuit board having a prepreg with a supporting base film vacuum laminated
9a, 9b: SUS plate
10, 11, 12: Prepreg with a supporting base film
100, 101, 102: Prepreg roll

### DESCRIPTION OF EMBODIMENTS

A method for laminating a prepreg of the present invention can contribute to decrease in thickness of a laminate to be obtained and can improve handling of the prepreg by using the prepreg roll specified in the present invention, therefore, productivity can be improved.

### (Preparation of Prepreg Roll)

Firstly, a process of preparing the prepreg roll of the present invention will be described.

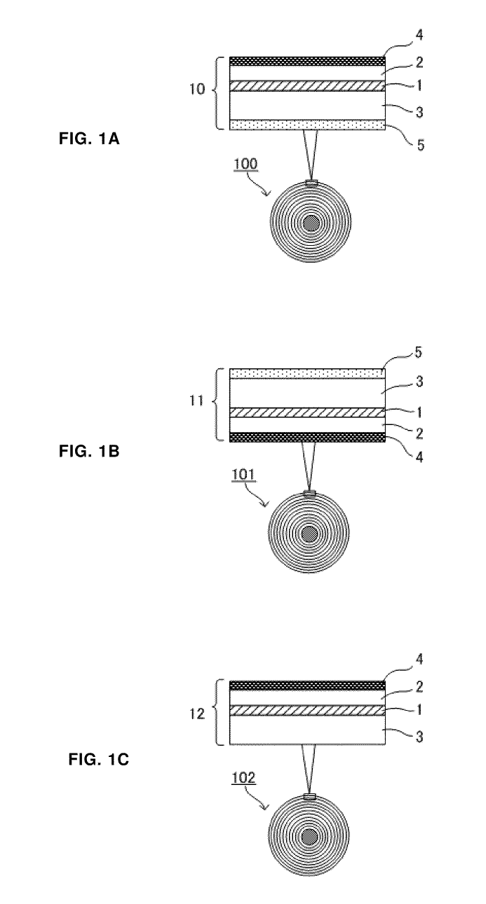

The method for laminating the prepreg of the present invention uses a prepreg roll selected from any of the following prepreg rolls a) to c) shown in FIGS. 1A to 1C:

a) a prepreg roll 100 (FIG. 1A) comprising a prepreg 10 comprising a core layer 1 having a continuous sheet-like base material, a first resin layer 2 formed on one surface of the core layer 1 and a second resin layer 3, being thicker than the first resin layer 2, formed on the other surface of the core layer 1, and a supporting base film 4 selected from a peelable film and a metal foil covering a first resin layer side of the prepreg 10, wherein a second resin layer side of the prepreg 10 is covered with a peelable film 5, and the prepreg 10 with the supporting base film 4 is rolled up into a roll, the second resin layer side being disposed inside;

b) a prepreg roll 101 (FIG. 1B) comprising a prepreg 11 comprising a core layer 1 having a continuous sheet-like base material, a first resin layer 2 formed on one surface of the core layer 1 and a second resin layer 3, being thicker than the first resin layer 2, formed on the other surface of the core layer 1, and a supporting base film 4 selected from a peelable film and a metal foil covering a first resin layer side of the prepreg 11, wherein a second resin layer side of the prepreg 11 is covered with a peelable film 5, and the prepreg 11 with the supporting base film 4 is rolled up into a roll, the first resin layer side being disposed inside; and

c) a prepreg roll 102 (FIG. 1C) comprising a prepreg 12 comprising a core layer 1 having a continuous sheet-like base material, a first resin layer 2 formed on one surface of the core layer 1 and a second resin layer 3, being thicker than the first resin layer 2, formed on the other surface of the core layer 1, and a supporting base film 4 selected from a peelable film and a metal foil covering a first resin layer side of the prepreg 12, wherein the prepreg 12 with the supporting base film 4 is rolled up into a roll, the second resin layer side being disposed inside.

Hereinafter, the prepreg with the supporting base film constituting the prepreg roll will be described.

The prepreg with the supporting base film has the first resin layer formed on one surface of the core layer and the second resin layer formed on the other surface of the core layer, and the first resin layer side of the prepreg, in which the second resin layer is thicker than the first resin layer, is covered with the supporting base film. Further, the second resin layer side may be covered with the peelable film. In distinction from the prepreg with the supporting base film, a laminate constituted only with the core layer, the first resin layer, and the second resin layer is referred to as a prepreg.

The core layer is mainly constituted with the continuous sheet-like base material and functions to improve the strength of the prepreg.

The core layer may be constituted with the sheet-like base material alone, or a part of the resin of the first resin layer and second resin layer may be impregnated with the sheet-like base material.

Examples of the sheet-like base material include fiber base materials including glass fiber base materials such as glass woven fabric and glass nonwoven fabric, and organic fiber base materials including synthesized fiber base materials constituted with woven or nonwoven fabric mainly comprising: polyamide-based resin fibers such as polyamide resin fibers, aromatic polyamide resin fibers and wholly aromatic polyamide resin fibers; polyester-based resin fibers such as polyester resin fibers, aromatic polyester resin fibers and wholly aromatic polyester resin fibers; polyimide resin fibers; and fluorinated resin fibers, paper base materials mainly comprising craft paper, cotton linter paper, and mixed paper of linter and craft pulp, and resin films such as a polyester and a polyimide. Among the above, the glass fiber base materials are preferable. Thereby, the strength of the prepreg can be improved. In addition, the thermal expansion coefficient of the prepreg can be decreased.

Examples of the glass constituting the glass fiber base materials include E glass, C glass, A glass, S glass, D glass, NE glass, T glass, H glass and Q glass. Among the above, S glass and T glass are preferable since the elasticity of the glass fiber base material can be highly increased, and the thermal expansion coefficient of the glass fiber base materials can be decreased so that the thermal expansion coefficient of the prepreg can be decreased.

The thickness of the sheet-like base material is not particularly limited. To obtain a thin prepreg, the thickness of the sheet-like base material is preferably 30 μm or less, more preferably 25 μm or less, still more preferably from 10 to 20 μm. If the thickness of the sheet-like base material is within the above range, balance of the reduction in layer thickness and the strength of the prepreg with the supporting base film can be excellent. Further, the processability and reliability of interlayer connection can be excellent.

A first resin composition constituting the first resin layer and a second resin composition constituting the second resin layer contain, for example, a curable resin, a curing additive, a filler, etc. The first resin composition and the second resin composition may be the same or different from each other. The first resin composition preferably has a resin composition excellent in adhesion to a metal foil, and the second resin composition preferably has a resin composition excellent in circuit embedding property.

To improve the adhesion between the resin composition and the metal foil, it is effective to use a curable resin excellent in adhesion to the metal foil, to use a curing additive which improves the adhesion to the metal foil, to use an inorganic filler soluble in acid, or to use an inorganic filler and an organic filler in combination, as components of the resin composition.

To improve the circuit embedding property of the resin composition, it is effective to make the viscosity of the resin composition upon melting by heat be 10⁴ Pa·s or less by decreasing the amount of the inorganic filler to be added in the resin composition to the extent that the properties of the inorganic filler is not deteriorated or using a curable resin having a low viscosity as a component of the resin composition. In addition, the circuit embedding property of the resin composition can be improved by making the viscosity of the resin composition upon melting by heat be 10⁴ Pa·s or less to prevent proceeding of B-stage of the curable resin by drying by heat, increasing the pressure upon molding, or performing vacuum molding.

The different resin compositions may be at least different in one among kind of constituent material, charging amount, and molecular weight of resins contained therein.

The curable resin used for the first resin composition and the second resin composition is not particularly limited as long as it is a resin composition having thermal flowability and being in a solid state at ordinary temperature, wherein the composition comprises a thermosetting resin and/or polymer as main components, softens by heating, and has film forming property, and further, the resin composition becomes to satisfy properties required for an interlayer insulating material, such as heat resistance and electrical property, by thermal curing. As the curable resin, a known curable resin used as an insulating material can be used. The examples include resins having a triazine ring such as phenol resins, epoxy resins, cyanate resins, urea resins, and melamine resins, isocyanate resins, unsaturated polyester resins, maleimide resins, urethane resins, silicone resins, benzocyclobutene resins, resins having benzoxazine rings, and vinyl resins, and are not limited thereto. These curable resins may be used alone, or a mixture of two or more kinds of the above resins may be used.

Among the above curable resins, as the curable resin used for the first resin composition and the second resin composition, the cyanate resins (including prepolymers of the cyanate resins) are particularly preferable. This is because the thermal expansion coefficient of the prepreg can be decreased, and further, electrical properties (low-dielectric constant and low-dielectric tangent) of the prepreg are excellent.

The cyanate resin can be obtained by, for example, reacting a cyanogen halide compound with phenol, and if necessary, polymerizing them by a method such as heating. The specific examples include bisphenol type cyanate resins such as novolac type cyanate resins, bisphenol A type cyanate resins, bisphenol E type cyanate resins and tetramethyl bisphenol F type cyanate resins. Among the above, the novolac type cyanate resins are preferable. Thereby, heat resistance can be improved by increase of cross-linking density, and flame resistance can be improved. The reason thereof is considered that novolac type cyanate resins form a triazine ring (s) after a curing reaction, and further have a high ratio of benzene ring due to its structure and easily carbonize. Furthermore, even when the thickness of the prepreg decreases (thickness: 35 μm or less), excellent rigidity can be imparted to the prepreg. Particularly, the rigidity upon heating is excellent, so that reliability upon mounting a semiconductor element is also excellent.

These cyanate resins may be used alone, or a mixture of two or more kinds may be used. In addition, these cyanate resins may be oligomerized in advance, and may contain a triazine ring in which cyanate groups are trimerized. Further, for the cyanate resin, an organometallic salt such as naphthenate or octylic acid salt, or a metallo-organic complex such as an acetylaceton complex may be used as a curing catalyst, and a compound containing a phenolic hydroxyl group may be used as a curing accelerator. These curing catalyst and accelerator may be used alone or in combination of two or more kinds.

In the case of using the cyanate resin (particularly, the novolac type cyanate resin) as the curable resin, it is preferable to use an epoxy resin in combination with the cyanate resin. Examples of the epoxy resin include phenol novolac type epoxy resins, bisphenol type epoxy resins, naphthalene type epoxy resins, and arylalkylene type epoxy resins. Among the above, the arylalkylene type epoxy resins are preferable. Thereby, the hygroscopic solder heat resistance and the flame resistance can be improved.

These epoxy resins may be used alone or a mixture of two or more kinds may be used. A curing agent used for the epoxy resin is not particularly limited as long as it can cure the epoxy resin. The examples include polyfunctional phenols, polyfunctional alcohols, amines, imidazole compounds, acid anhydrides, and organic phosphorous compounds. These curing agents of the epoxy resin may be used alone or in combination of two or more kinds.

The curable resin preferably contains an inorganic filler. Thereby, even though the thickness of the prepreg is decreased to 35 μm or less, excellent strength can be imparted. Further, low-thermal expansion characteristics of the prepreg can be improved.

Examples of the inorganic filler include talc, alumina, glass, silica, mica, aluminum hydroxide, magnesium hydroxide, etc. Among the above, silica is preferable, and fused silica (particularly, spherical fused silica) is more preferable, from the viewpoint of excellent low-thermal expansion characteristics. The shape of the silica includes fractured shape and spherical shape, and is selected according to the purpose such as using spherical silica to decrease melting viscosity of the resin composition in order to secure impregnation into fiber base materials.

It is preferable for the curable resin to use a coupling agent. The coupling agent can improve the wettability of an interface between the curable resin and the inorganic filler. Thereby, the curable resin and the inorganic filler can be uniformly fixed on the sheet-like base material, and the heat resistance, particularly the solder heat resistance after absorption, can be improved.

The coupling agent is not particularly limited and a known coupling agent can be used. For example, it is preferable to use one or more coupling agents selected from epoxy silane coupling agents, cationic silane coupling agents, amino silane coupling agents, titanate coupling agents and silicone oil type coupling agents. Thereby, the wettability of the interface between the resin and the inorganic filler can be particularly increased and the heat resistance can be further improved.

In considering the dielectric property and processability, the curable resin may use a thermoplastic resin such as a phenoxy resin, a polyimide resin, a polyamide-imide resin, a polyphenylene oxide resin or a polyether sulfone resin. The thermoplastic resin is not particularly limited thereto, and it may be used alone or in combination of two or more kinds.

To the curable resin, if necessary, additives other than the above components such as a defoaming agent, a leveling agent, a pigment, an antioxidant, a flame retardant, etc. may be added.

The thickness (after coating and drying) of the first resin layer constituted with the first resin composition is preferably from 0.5 to 20 μm, more preferably from 1 to 5 μm. If the thickness is within the above range, the total thickness of the prepreg can be particularly decreased.

The surface roughness of the first resin layer (after roughening treatment) is not particularly limited, and is preferably 2 μm or less, more preferably 0.5 μm or less. If the surface roughness is within the above range, inner circuit adhesion is particularly excellent upon forming fine circuits.

The above surface roughness can be obtained, for example, by means of a laser microscope or a contact type surface roughness measuring machine.

The thickness (after coating and drying) of the second resin layer constituted with the second resin composition is preferably from 4 to 50 μm, more preferably from 6 to 25 μm. The thickness of the second resin layer depends on the thickness of the inner circuit to cover, and is thick enough to embed the inner circuit. That is, the thickness t2 represented by the following Formula 1 is preferably from 0.1 to 5 μm, more preferably from 1 to 3 μm. If the thickness t2 is within the above range, the embedding property of the inner circuit is excellent, and the total thickness can be particularly decreased.

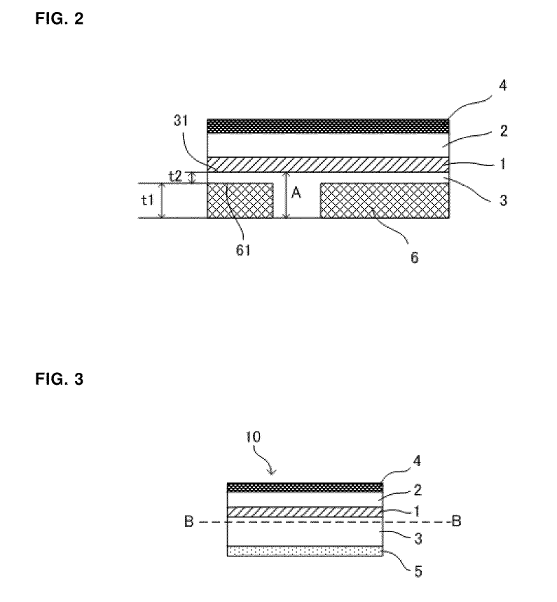

A=t1×(1−S/100)+t2 Formula 1

wherein A [μm] is the thickness of the second resin layer 3; t1 [μm] is the thickness of the inner circuit 6; “S” refers to the copper remaining rate thereof; and t2 is the thickness from the end 61 of the inner circuit 6 (the surface of the inner circuit bonded to the second resin layer) to the end 31 of the second resin layer 3 (the surface of the second resin layer bonded to the core layer) (FIG. 2).

The thermal expansion coefficient in a surface (X, Y) direction of the second resin layer is not particularly limited, and is preferably 20 ppm or less, more preferably from 5 to 16 ppm. If the thermal expansion coefficient is within the above range, particularly, the connection reliability, the mounting reliability of a semiconductor element, etc. can be excellent.

The thermal expansion coefficient in the surface direction can be evaluated, for example, by means of a TMA (manufactured by TA Instruments) by heating at 10° C./m.

The first resin layer is covered with the supporting base film selected from a peelable film and a metal foil.

Examples of the peelable film include polyolefin such as polyethylene and polypropylene; polyester such as polyethylene terephthalate and polybutylene terephthalate; released paper such as polycarbonate and silicone sheet; and a thermoplastic resin film having heat resistance such as a fluorine resin and a polyimide resin. Among the above films, the film constituted with polyester is most preferable. Thereby, the film can be easily removed from the insulating layer with appropriate strength.

Examples of the metal foil include metal foils such as a copper foil and an aluminum foil; and a copper thin film formed by performing copper plating on the film. Among the above, the copper thin film is preferable. Thereby, fine circuits can be easily formed.

The second resin layer may be covered with the peelable film. As the peelable film, a peelable film similarly as the above can be used.

In the prepreg with the supporting base film of the present invention, as shown in FIG. 3, the core layer 1 mainly constituted with the sheet-like base material is eccentrically-located in the thickness direction of the prepreg 10 with the supporting base film. Thereby, the amount of resin can be adjusted depending on circuit patterns. The core layer 1 being eccentrically-located in the thickness direction of the prepreg 10 with the supporting base film means, as shown in FIG. 3, the center of the core layer 1 is disposed away from the center line B-B of the thickness direction of the prepreg 10.

The thickness of the prepreg with the supporting base film excluding the thickness of the supporting base film is preferably from 14.5 to 100 μm, more preferably from 17 to 50 μm. If the thickness is within the above range, the thickness of the printed wiring board obtained by using the prepreg with the supporting base film can be particularly decreased.

The prepreg with the supporting base film of the present invention is used as a prepreg roll in which the prepreg is rolled in the shape of a roll. The prepreg with the supporting base film has the first resin layer, in which the thickness of the layer is relatively thin, and the second resin layer, in which the thickness of the layer is relatively thick, to contribute to the reduction in the layer thickness. Thus, the shrink characteristics of the second resin layer are higher than that of the first resin layer. When the prepreg with the supporting base film in the form of sheet is layered on the circuit board, the prepreg with the supporting base film curls toward the second resin layer side (disposing the second resin layer side inside) due to the difference of shrink characteristics between the resin layers, and handling and precise laminate are difficult. In addition, if the second resin layer side is covered with the peelable film having relatively high shrink characteristics, the shrinkage tension of the peelable film is released upon peeling the peelable layer to layer the prepreg in the form of sheet on the circuit board. Thereby, the prepreg with the supporting base film curls toward the first resin layer side (disposing the first resin layer side inside), and handling and precise laminate are difficult. To the contrary, in the case of using the prepreg with the supporting base film in the form of a roll as a prepreg roll, by unreeling the prepreg with the supporting base film from the roll when layering and laminating the prepreg with the supporting base film on the circuit board, the tension is applied on the prepreg with the supporting base film and the prepreg with the supporting base film is stretched, so that handling can be easy and precise laminate can be achieved. Therefore, the productivity of the printed wiring board improves.

Hereinafter, the prepreg roll of the present invention will be described.

The prepreg roll is a roll in which the prepreg with the supporting base film is rolled up in the form of a roll, and includes: a) a prepreg roll comprising the prepreg, and the supporting base film selected from a peelable film and a metal foil covering the first resin layer side of the prepreg, wherein the second resin layer side of the prepreg is covered with a peelable film, and the prepreg with the supporting base film is rolled up into a roll, the second resin layer side being disposed inside; b) a prepreg roll comprising the prepreg, and the supporting base film selected from a peelable film and a metal foil covering the first resin layer side of the prepreg, wherein the second resin layer side of the prepreg is covered with a peelable film, and the prepreg with the supporting base film is rolled up into a roll, the first resin layer side being disposed inside; and c) a prepreg roll comprising the prepreg, the supporting base film selected from a peelable film and a metal foil covering a first resin layer side of the prepreg, wherein the prepreg with the supporting base film is rolled up into a roll, the second resin layer side being disposed inside.

The prepreg roll may be in any embodiment from a) to c) described above. Since shrink characteristics of the second resin layer, which is thicker than the first resin layer, is higher than that of the first resin layer, the prepreg rolls a) and c), which are rolled up into a roll, the second resin layer side disposed inside, are preferable from the viewpoint of easy handling. The prepreg roll a), having the supporting base film on the first resin layer and the peelable film on the second resin layer, is more preferable from the viewpoint that impurity from outside is less likely to be contained in the second resin layer.

Both surfaces of the supporting base film of the prepreg roll c) have release property.

The prepreg with the supporting base film is rolled up into a roll, the first resin layer side disposed inside means the prepreg with the supporting base film is wound so that the first resin layer is on the inner side (on the core side of the roll) than the second resin layer in the outermost prepreg with the supporting base film of the roll. The prepreg with the supporting base film is rolled up into a roll, the second resin layer side disposed inside means the prepreg with the supporting base film is wound so that the second resin layer is on the inner side (on the core side of the roll) than the first resin layer in the outermost prepreg with the supporting base film of the roll.

Next, a method for obtaining the prepreg roll of the present invention will be described taking the prepreg roll 100 of the above a) as shown in FIG. 1A as a representative example. The prepreg roll 100 can be obtained by rolling up the prepreg with the supporting base film which is obtained by, for example, a method comprising the steps of: producing a first carrier material, in which the first resin composition is applied on the supporting base film, and a second carrier material, in which the second resin composition is applied on the peelable film; and laminating the above obtained first and second carrier materials on the sheet-like base material.

The first carrier material can be obtained by, for example, a method for applying a varnish of the first resin composition on the supporting base film. Similarly, the second carrier material can also be obtained by, for example, a method for applying a varnish of the second resin composition on the peelable film.

The method for laminating the first and second carrier materials on the sheet-like base material comprises the steps of: layering the first carrier material on one surface of the sheet-like base material; layering the second carrier material on the other surface of the sheet-like base material; and bonding them under reduced pressure by a laminate roll by means of a vacuum lamination apparatus. Since the bonding is performed under reduced pressure, even if unfilled parts exist inside of the sheet-like base material or at the bonded surfaces between the first carrier material and the sheet-like base material, and the second carrier material and the sheet-like base material, the unfilled parts can be changed reduced-pressure voids or substantially-vacuum voids. Therefore, voids, etc. are not present in the prepreg with the supporting base film to be finally obtained, thus, excellent molding state can be made. This is because the reduced-pressure void or substantially-vacuum void can be vanished by heat treatment that will be described hereinafter. As another apparatus which bonds the sheet-like base material to the first and second carrier materials under such a reduced pressure, for example, a vacuum box can be used. In the inner region of the glass woven fabric in the width direction (the region close to the center of the glass woven fabric in the width direction), the resin layer of the carrier material was bonded to one surface of the glass woven fabric and the carrier material was bonded to the other surface of the glass woven fabric. In the outer region of the glass woven fabric in the width direction (the region away from the center of the glass woven fabric in the width direction, and close to the end of the glass woven fabric in the width direction), the resin layer of the carrier material and the resin layer of the carrier material were bonded.

Next, after bonding the sheet-like base material and the first and second carrier materials, heat treatment is performed at the temperature of higher than the melting temperature of the resin composition constituting the first and second carrier materials by means of a hot air drying machine. Thereby, the reduced-pressure voids, etc. caused in the bonding step under reduced pressure can be vanished. The heat treatment can also be performed by means of infrared heating equipment, a heating roller, or a tabular hot press machine.

According to the above method, the prepreg roll 100 can be easily obtained even by using the sheet-like base material having a thickness of 30 μm or less. In the method of producing a conventional prepreg (for example, a method comprising the steps of impregnating a sheet-like base material with a resin varnish and drying by means of a general coating machine), it has been difficult to obtain a prepreg by carrying a resin material on a sheet-like base material having a thickness of 30 μm or less. That is, there are cases that when the thin sheet-like base material is impregnated with the thermosetting resin to be conveyed through a number of transport rolls, and the amount of the resin material impregnated with the sheet-like base material is adjusted, stress is applied to the sheet-like base material, thus, the mesh of the sheet-like base material is opened (expanded) and the sheet-like base material is cutoff when winding.

To the contrary, in the above method of the present invention, each carrier material can be carried by the sheet-like base material having a thickness of 30 μm or less, thereby, a prepreg roll having a thickness of 35 μm or less can be easily obtained in addition to obtaining the prepreg roll having a general thickness. By using the above prepreg roll, the thickness of the insulating layer after forming the substrate between the conducting circuit layers can be 25 μm or less. If the thickness between the conducting circuit layers can be 25 μm or less, the thickness of the printed wiring board to be finally obtained can be decreased.

An example of another method for obtaining such a prepreg roll 100 includes a method comprising the steps of: impregnating one surface of the sheet-like base material with a resin varnish which forms the first resin layer; layering the supporting base film thereon; impregnating the other surface of the sheet-like base material with a resin varnish which forms the second resin layer; layering the peelable film thereon; and rolling up the obtained prepreg with the supporting base film into a roll with the second resin layer side disposed inside while hot press.

Further, examples of other methods for obtaining the prepreg roll 100 include a method (1) comprising the steps of: applying a resin varnish on the sheet-like base material to impregnate followed by drying; thinly applying the resin varnish which forms the second resin layer on one surface of thus obtained sheet-like base material by means of a roll coater, comma coater, etc. and drying to be in the B-stage; layering a peelable film on the resin composition layer which forms the second resin layer in the B-stage; layering a supporting base film on the other side of the resin composition layer; laminating them under heat and pressure; and rolling up the prepreg with the supporting base film into a roll; and a method (2) comprising the steps of: applying a resin vanish on the sheet-like base material to impregnate followed by drying; layering a supporting base film on one side of the resin composition layer which forms a first resin layer; producing a B-stage resin composition sheet with a peelable film which forms the second resin layer separately; layering one side of the resin composition layer of the prepreg with the supporting base film on the resin composition side of the B-stage resin composition sheet with the peelable film which forms the second resin layer; laminating them under heat and pressure; and rolling up the prepreg with the supporting base film into.

### (Lamination of Prepreg on Circuit Board)

The method for laminating the prepreg of the present invention uses the prepreg roll described above, and comprises the following steps 2) to 4):

2) unreeling the prepreg with the supporting base film from the prepreg roll, peeling off the peelable film if the second resin layer is covered with the peelable film, and layering the prepreg with the supporting base film on a circuit board so that the second resin layer side of the prepreg with the supporting base film faces a circuit of the circuit board;

[2′] cutting the prepreg with the supporting base film at the positions before and after the circuit board into the same size (length) as that of the circuit board in the longitudinal direction (in the running direction of the production line), after the front end portion and rear end portion (about 2 mm wide) of the circuit board and the prepreg with the supporting base film thereof to be charged into the Vacuum & pressure laminator are subjected to tentative hot press;

3) vacuum laminating the prepreg with the supporting base film on the circuit board by hot press from a supporting base film side of the prepreg with the supporting base film through a heat-resisting rubber; and

4) smoothing a surface of the first resin layer contacting the supporting base film (the surface of the first resin layer bonded to the supporting base film) by hot press from the supporting base film side of the prepreg with the supporting base film by means of a metal plate for press and/or metal roll for laminate.

In the method for laminating the prepreg of the present invention, it is preferable further to comprise after the above step 4) of smoothing process, 5) sandwiching the circuit board having the prepreg with the supporting base film vacuum laminated between two SUS plates followed by curing at a temperature from 160 to 240° C. under ordinary pressure for 0.5 to 3 hours. By performing the above step 5) of curing process, generation of microvoids in the insulating layer can be prevented. Therefore, an insulating layer having excellent solder heat resistance and insulation reliability can be obtained.

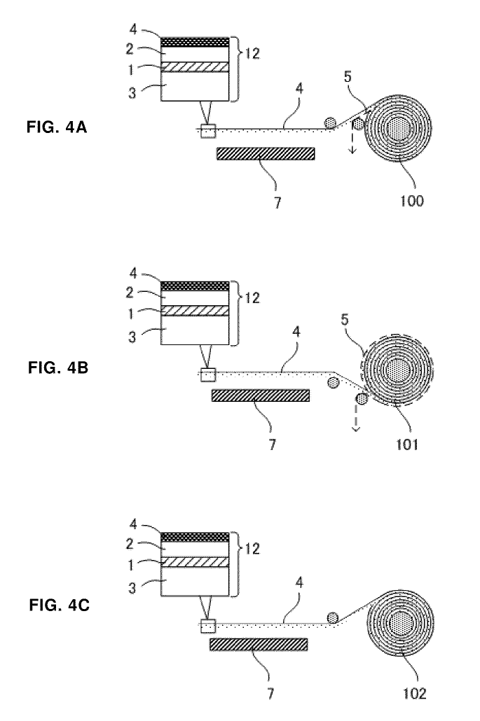

In the above step 2), the prepreg roll is placed so that the second resin layer side of the prepreg with the supporting base film faces the circuit board. That is, in the case of using the prepreg roll 100 (the above roll a)), the prepreg roll 100 is set on the line of the lamination process as shown in FIG. 4A. In the case of using the prepreg roll 101 (the above roll b)), the prepreg roll 101 is set on the line of the lamination process as shown in FIG. 4B. In the case of using the prepreg roll 102 (the above roll c)), the prepreg roll 102 is set on the line of the lamination process as shown in FIG. 4C. If the second resin layer is covered with the peelable film 5 (shown as dotted line in FIGS. 4A and 4B) as the prepreg rolls 100 and 101 in the prepreg roll, as shown in FIGS. 4A and 4B, the prepreg 12 with the supporting base film 4 (shown as a solid line (supporting base film 4) and dots (other layers) as well as the enlarged view in FIGS. 4A to 4C) is unreeled from the set prepreg roll while peeling off the peelable film 5 (the peeled peelable film 5 is shown by the dotted-line arrow directed downward of the figure in FIGS. 4A and 4B), and the prepreg 12 with the supporting base film 4 is layered on the circuit board 7 by facing the second resin layer 3 side of the prepreg 12 with the supporting base film 4 with the circuit board.

In the above step 3), the prepreg with the supporting base film is vacuum laminated on the circuit board by hot press from the supporting base film side through the heat-resisting rubber, and. The above step 3) can be performed by a commercially available vacuum laminator such as Vacuum applicator manufactured by Nichigo-Morton Co., Ltd., Vacuum & pressure laminator manufactured by MEIKI CO., LTD., or Vacuum laminator manufactured by TAISEI LAMINATOR CO., LTD. By vacuum laminating the prepreg with the supporting base film under the condition that the thickness of the second resin layer is thicker than a conductor of the inner circuit, the inner circuit pattern can be covered well.

The heating temperature is preferably in the range from 60 to 150° C., more preferably from 80 to 120° C.

The pressure applied is preferably in the range from 0.4 to 2.0 MPa, more preferably from 0.6 to 1.0 MPa.

In the above step 4), the circuit board having the prepreg with the supporting base film vacuum laminated is heated and pressed from the supporting base film side by means of a metal plate for press and/or a metal roll for laminate, to smooth the surface of the first resin layer contacting the supporting base film. Thereby, the surface smoothness of the surface of the resin composition layer contacting the supporting base film becomes excellent. The above step 4) can be performed, for example, by means of a commercially available laminator such as a hot press machine using SUS plate, etc. or a hot press laminator. By pressing and/or laminating the circuit board having the prepreg with the supporting base film vacuum laminated in the above step 4) under the condition of hot press as the same as or higher than that upon the vacuum laminate in the above step 3), the surface of the resin composition layer contacting the supporting base film can be smoothed.

The heating temperature is preferably in the range from 60 to 150° C., more preferably from 80 to 120° C.

The pressure applied is preferably in the range from 0.4 to 3.0 MPa, more preferably from 0.6 to 2.0 Pa.

The above step 4) may be performed after the above step 3), or at the same time as the above step 3). In addition, in the case of performing the above step 4) after the above step 3), the above step 4) may be performed in the state that the vacuum state is released, or maintained, or in the state that after the vacuum state is once released and then recovered.

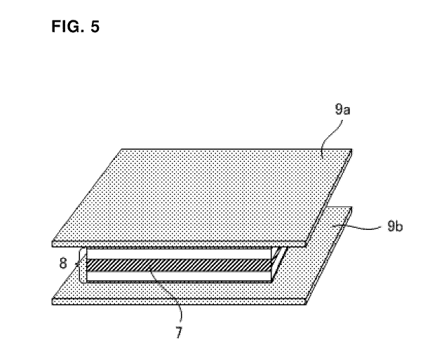

In the above step 5), as shown in FIG. 5, the curing process is performed by sandwiching the circuit board 8 having the prepreg with the supporting base film vacuum laminated between SUS plates 9a and 9b from both sides of the circuit board 8 at a temperature from 160 to 240° C. under ordinary pressure for 0.5 to 3 hours. The ordinary pressure used herein means the state not reducing pressure or not applying pressure, and refers to about 1 atm (about 101,325 Pa).

The area of the SUS plate 9a placed on the circuit board 8 having the prepreg with the supporting base film vacuum laminated, and the area of the SUS plate 9b placed under the circuit board 8 are not particularly limited as long as each area described above is larger than the circuit board 8 having the prepreg with the supporting base film vacuum laminated. It is, however, preferable that the area and form of SUS plate 9a and the area and form of SUS plate 9b are the same.

In addition, by performing the method for laminating the prepreg of the present invention, the printed wiring board contributing to decrease in layer thickness can be obtained with high productivity. Particularly, by laminating the circuit board and the prepreg with the supporting base film by the method for laminating the prepreg of the present invention, a multilayer printed wiring board can be easily obtained.

The method for laminating the prepreg of the present invention is not limited to the case of using the prepreg as an interlayer prepreg for buildup, and is applicable to a general adhesive film having thermal flowability, for example, dry films such as a solder resist, etc.

### EXAMPLES

The present invention will be hereinafter explained in detail with reference to Examples and Comparative examples. The present invention may not be limited thereto.

### Example 1

### 1. Preparation of Vanish of First Resin Layer

24 weight % of a cyanate resin (product name: PRIMASET PT-30; manufactured by LONZA Japan; weight average molecular weight: about 2,600), 24 weight % of a biphenyldimethylene type epoxy resin (product name: NC-3000; manufactured by Nippon Kayaku Co., Ltd.; epoxy equivalent: 275) as an epoxy resin, 11.8 weight % of a phenoxy resin (product name: EP-4275; manufactured by Japan Epoxy Resins Co., Ltd.; weight average molecular weight: 60,000; a copolymer of bisphenol A type epoxy resin and bisphenol F type epoxy resin, having an epoxy group at terminal positions) as a phenoxy resin, and 0.2 weight % of an imidazole compound (manufactured by SHIKOKU CHEMICALS CORPORATION; 2-phenyl-4,5-dihydroxymethylimidazole) as a curing catalyst were dissolved in methyl ethyl ketone. Further, 39.8 weight % of spherical fused silica (product name: SO-25H; manufactured by Admatechs Company Limited; average particle diameter: 0.5 μm) as an inorganic filler and 0.2 weight % of epoxy silane type coupling agent (product name: A-187; manufactured by Nippon Unicar Company Limited) were added therein followed by agitating for 60 minutes by means of a high speed agitator. Thus, a varnish for a first resin layer having a solid content of 60 weight % was prepared.

### 2. Preparation of Varnish of Second Resin Layer

15 weight % of novolac type cyanate resin (product name: PRIMASET PT-30: manufactured by LONZA Japan; weight average molecular weight: about 2,600) as a thermosetting resin, 8.7 weight % of biphenyldimethylene type epoxy resin (product name: NC-3000; manufactured by Nippon Kayaku Co., Ltd.; epoxy equivalent: 275) as an epoxy resin, and 6.3 weight % of biphenyldimethylene type phenol resin (product name: GPH-65; manufactured by Nippon Kayaku Co., Ltd.; hydroxyl group equivalent: 200) as a phenol resin were dissolved in methyl ethyl ketone. Further, 69.7 weight % of spherical fused silica (product name: SO-25H; manufactured by Admatechs Company Limited; average particle diameter: 0.5 μm) as an inorganic filler and 0.3 weight % of epoxy silane type coupling agent (product name: A-187; manufactured by Nippon Unicar Company Limited) were added therein followed by agitating for 60 minutes by means of a high speed agitator. Thus, a varnish for a second resin layer having a solid content of 60 weight % was prepared.

### 3. Production of Carrier Material

The varnish for the first resin layer was applied on a copper foil (product name: 3EC-VLP; manufactured by MITSUI MINING & SMELTING CO., LTD; thickness: 12 μm; width: 480 mm) being a supporting base film by means of a comma coater, and dried at 170° C. for 3 minutes by means of a drying machine. Thereby, a resin layer (to be a first resin layer later) having a thickness of 8 μm and a width of 410 mm was formed in the center of the copper foil in the width direction. Thus, a carrier material 2a was obtained.

Similarly as in the above method, the amount to apply the varnish for the second resin layer was adjusted and a resin layer (to be a second resin layer later) having a thickness of 17 μm and width of 410 mm was formed in the center of a carrier film (polyethylene terephthalate film; product name: SFB-38; manufactured by Mitsubishi Plastics, Inc.; thickness: 38 μmm; width: 480 mm) in the width direction. Thus, a carrier material 3a was obtained.

### 4. Production of Prepreg with Supporting Base Film

Glass woven fabric (cloth type: #1017; width: 360 mm; thickness: 15 μm; basis weight: 13 g/m²) was used as a fiber base material, and a prepreg was produced by means of a vacuum lamination apparatus and a hot air drying machine.

Specifically, the resin layer of the carrier material 2a was layered on one surface of the glass woven fabric and the resin layer of the carrier material 3a was layered on the other surface of the glass woven fabric so that the carrier material 2a and the carrier material 3a were located in the center of the glass woven fabric in width direction. Then, the carrier material 2a, the glass woven fabric and the carrier material 3a were bonded under reduced pressure of 1,330 Pa by means of a laminate roll heated to 80° C. In the inner region of the glass woven fabric in the width direction (the region close to the center of the glass woven fabric in the width direction), the resin layer of the carrier material 2a was bonded to one surface of the glass woven fabric and the carrier material 3a was bonded to the other surface of the glass woven fabric. In the outer region of the glass woven fabric in the width direction (the region away from the center of the glass woven fabric in the width direction, and close to the end of the glass woven fabric in the width direction), the resin layer of the carrier material 2a and the resin layer of the carrier material 3a were bonded.

Next, the above bonded laminate was conveyed through a lateral transport type hot air drying machine heated to 120° C. for 2 minutes to conduct heat treatment without applying pressure. Thereby, a prepreg with the supporting base film having a thickness of 30 μm (first resin layer: 3 μm; fiber base material: 15 μm; second resin layer: 12 μm) was obtained. Thereafter, the prepreg with the supporting base film was rolled up in the form of a roll with the second resin layer at the inside. Thus, a prepreg roll (roll a)) was obtained.

### 5. Lamination of Prepreg with Supporting Base Film on Circuit Board

The prepreg with the supporting base film was laminated on a circuit board by means of Vacuum & pressure laminator (product name: MVLP-500/600-IIA; manufactured by MEIKI CO., LTD.) by the following steps [1] to [4]:

[1] setting the prepreg roll (roll a)) on the line of Vacuum & pressure laminator as shown in FIG. 4A; unreeling the prepreg 12 with the supporting base film 4 from the roll 100; peeling off the peelable film 5 covering the second resin layer 3; and layering the prepreg 12 with the supporting base film 4 on the circuit of the circuit board 7 (circuit thickness: 18 μm; copper remaining rate in the surface: 50%) so that the second resin layer side of the prepreg 12 with the supporting base film 4 faces the circuit board 7;

[2] cutting the prepreg with the supporting base film at the positions before and after the circuit board into the same size (length) as that of the circuit board in the longitudinal direction (in the running direction of the production line), after the front end portion and rear end portion (about 2 mm wide) of the circuit board and the prepreg with the supporting base film thereof to be charged into the Vacuum & pressure laminator were subjected to tentative hot press;

[3] vacuum laminating the prepreg with the supporting base film on the circuit board by hot press from the supporting base film side of the prepreg with the supporting base film through a heat-resisting rubber at 100° C. under 0.8 MPa for 30 seconds in the Vacuum & pressure laminator; and

[4] smoothing a surface of the first resin layer contacting the supporting base film by hot press from the supporting base film side of the prepreg with the supporting base film by means of a SUS plate for press at 100° C. under 1.0 MPa for 60 seconds.

### 6. Curing of Prepreg with Supporting Base Film

Both sides of the circuit board having the prepreg with the supporting base film laminated was sandwiched by SUS plates larger than the circuit board followed by curing at 200° C. for 1.5 hours.

### Example 2

Example 2 was performed similarly as Example 1 except that a carrier film (polyethylene terephthalate film; product name: SFB-38; manufactured by Mitsubishi Plastics, Inc.; thickness: 38 μm; width: 480 mm) was used as the supporting base film.

### Example 3

Example 3 was performed similarly as Example 1 except that the prepreg roll (roll b)) obtained by rolling the prepreg with the supporting base film with the first resin layer disposed inside was used, and the lamination process of the prepreg with the supporting base film was changed to the following steps [1] to [4]:

[1] setting the prepreg roll (roll b)) on the line of Vacuum & pressure laminator as shown in FIG. 4B; unreeling the prepreg 12 with the supporting base film 4 from the roll 101; peeling off the peelable film 5 covering the second resin layer 3; and layering the prepreg 12 with the supporting base film 4 on the circuit of the circuit board 7 (circuit thickness: 18 μm; copper remaining rate in the surface: 50%) so that the second resin layer side of the prepreg 12 with the supporting base film 4 faces the circuit board 7;

[2] cutting the prepreg with the supporting base film at the positions before and after the circuit board into the same size (length) as that of the circuit board in the longitudinal direction (in the running direction of the production line), after the front end portion and rear end portion (about 2 mm wide) of the circuit board and the prepreg with the supporting base film thereof to be charged into the Vacuum & pressure laminator were subjected to tentative hot press;

[3] vacuum laminating the prepreg with the supporting base film on the circuit board by hot press from the supporting base film side of the prepreg with the supporting base film through a heat-resisting rubber at 100° C. under 0.8 MPa for 30 seconds in the Vacuum & pressure laminator; and

[4] smoothing a surface of the first resin layer contacting the supporting base film by hot press from the supporting base film side of the prepreg with the supporting base film by means of a SUS plate for press at 100° C. under 1.0 MPa for 60 seconds.

### Example 4

Example 4 was performed similarly as Example 1 except that the prepreg roll (roll c)), in which a peelable film was used as the supporting base film, and the peelable film on the second resin layer side was not used, and the lamination process of the prepreg was changed to the following steps [1] to [4]:

[1] setting the prepreg roll (roll c)) on the line of Vacuum & pressure laminator as shown in FIG. 4C; unreeling the prepreg 12 with the supporting base film 4 from the roll 102; peeling off the peelable film 5 covering the second resin layer 3; and layering the prepreg 12 with the supporting base film 4 on the circuit of the circuit board 7 (circuit thickness: 18 μm; copper remaining rate in the surface: 50%) so that the second resin layer side of the prepreg 12 with the supporting base film 4 faces the circuit board 7;

[2] cutting the prepreg with the supporting base film at the positions before and after the circuit board into the same size (length) as that of the circuit board in the longitudinal direction (in the running direction of the production line), after the front end portion and rear end portion (about 2 mm wide) of the circuit board and the prepreg with the supporting base film thereof to be charged into the Vacuum & pressure laminator were subjected to tentative hot press;

[3] vacuum laminating the prepreg with the supporting base film on the circuit board by hot press from the supporting base film side of the prepreg with the supporting base film through a heat-resisting rubber at 100° C. under 0.8 MPa for 30 seconds in the Vacuum & pressure laminator; and

[4] smoothing a surface of the first resin layer contacting the supporting base film by hot press from the supporting base film side of the prepreg with the supporting base film by means of a SUS plate for press at 100° C. under 1.0 MPa for 60 seconds.

### Comparative Example 1

The prepreg roll (roll a)) produced in Example 1 was unreeled, and the prepreg with the supporting base film was cut into a sheet in the same size as the circuit board. The peelable film was peeled off, and the prepreg with the supporting base film was layered on the circuit of the circuit board (circuit thickness: 18 μm; copper remaining rate in the surface: 50%) so that the second resin layer side of the prepreg with the supporting base film faces the circuit board. Thereafter, the above steps 5 [3] and 6 were performed.

### Comparative Example 2

The prepreg roll (roll b)) produced in Example 3 was unreeled, and the prepreg with the supporting base film was cut into a sheet in the same size as the circuit board. The peelable film was peeled off, and the prepreg with the supporting base film was layered on the circuit of the circuit board (circuit thickness: 18 μm; copper remaining rate in the surface: 50%) so that the second resin layer side of the prepreg with the supporting base film faces the circuit board. Thereafter, the above steps 5[3] and 6 were performed.

### Comparative Example 3

The prepreg roll (roll c)) produced in Example 4 was unreeled, and the prepreg with the supporting base film was cut into a sheet in the same size as the circuit board. The prepreg with the supporting base film was layered on the circuit of the circuit board (circuit thickness: 18 μm; copper remaining rate in the surface: 50%) so that the second resin layer side of the prepreg with the supporting base film faces the circuit board. Thereafter, the above steps 5[3] and 6 were performed.

### Comparative Example 4

Comparative example 4 was performed similarly as Example 1 except that the prepreg with the supporting base film was laminated on the circuit board by means of a roll laminator (product name: VA-700 type; manufacture by Taisei Laminator Co., Ltd.) under ordinary pressure.

### Comparative Example 5

Comparative example 5 was performed similarly as Example 1 except that the prepreg roll (roll a)) produced in Example 1 was unreeled, the prepreg with the supporting base film was cut into a sheet in the same size as the circuit board, the peelable film was peeled off, and the prepreg with the supporting base film was layered on the circuit of the circuit board (circuit thickness: 18 μm; copper remaining rate in the surface: 50%) so that the second resin layer side of the prepreg with the supporting base film faces the circuit board instead of the above steps 5[1] and [2], and thereafter, the prepreg with the supporting base film was laminated on the circuit board by continuously performing the above steps 5 [3], 5[4] and 6 by means of a vacuum press (product name: KVHC-II; manufactured by Kitagawa Seiki Co., Ltd.).

Evaluation method will be hereinafter described.

In each Example and Comparative example, the lamination of the prepreg with the supporting base film on the circuit board of 480 mm width grid was performed for 100 times (100 sheets), and the defects 1 to 5 described below were counted to calculate yields. In addition, operating times 6 were also compared.

1. Cracking of prepreg: defect due to deformation of a prepreg with a supporting base film upon setting or transporting the prepreg with the supporting base film.

2. Out of alignment of prepreg: defect due to deformation of a prepreg with a supporting base film upon transporting the prepreg with the supporting base film.

3. Involving foreign substances in a roll: defect due to involving foreign substances in a roll upon cutting a prepreg with a supporting base film and upon setting the prepreg with the supporting base film to a circuit board.

4. Defect of embedding: defect caused by not completely pouring a resin layer into a concave portion of a circuit.

5. Voids after curing: defect of voids generation between circuit board and resin layer, or resin layer and copper foil after curing.

6. Operating time: judgment of o, Δ and x are as follows:

o: time to process 100 circuit boards having a prepreg with a supporting base film was less than 5 hours;

Δ: time to process 100 circuit boards having a prepreg with a supporting base film was 5 hours or more and less than 8 hours; and

x: time to process 100 circuit boards having a prepreg with a supporting base film was 8 hours or more.

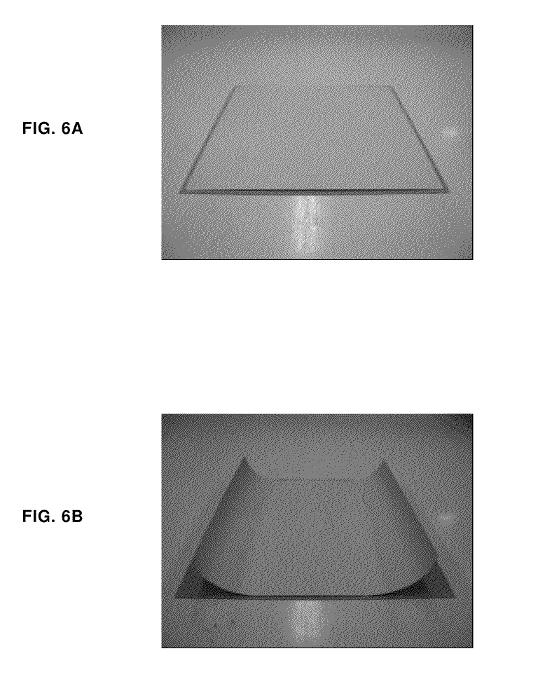

FIG. 6A is a photograph showing the prepreg with the supporting base film (after the prepreg with the supporting base film was layered on the circuit board, and before vacuum laminating) obtained in Example 1, and FIG. 6B is a photograph showing the prepreg with supporting base film (after the prepreg with the supporting base film was layered on the circuit board, and before vacuum laminating) obtained in Comparative example 1. As shown in the photographs, the prepreg with the supporting base film in Comparative example 1 curled. To the contrary, the prepreg with the supporting base film in Example 1 did not curl.

TABLE 1

| | | | | | Comparative | Comparative | Comparative | Comparative | Comparative |
|---|---|---|---|---|---|---|---|---|---|
| | Example 1 | Example 2 | Example 3 | Example 4 | example 1 | example 2 | example 3 | example 4 | example 5 |
| Roll | a) | a) | b) | c) | Sheet of a) | Sheet of a) | Sheet of c) | a) | Sheet of a) |
| Carrier material | Copper foil | PET | Copper foil | Copper foil | Copper foil | PET | Copper foil | Copper foil | Copper foil |
| Lamination | Vacuum & | Vacuum & | Vacuum & | Vacuum & | Vacuum & | Vacuum & | Vacuum & | Roll | Vacuum |
| apparatus | pressure | pressure | pressure | pressure | pressure | pressure | pressure | laminator | press |
| | laminator | laminator | laminator | laminator | laminator | laminator | laminator | under | |
| | | | | | | | | ordinary | |
| | | | | | | | | pressure | |
| Cracking of prepreg | 0 | 0 | 0 | 0 | 63 | 55 | 67 | 0 | 2 |
| Out of alignment of | 0 | 0 | 0 | 0 | 33 | 40 | 38 | 2 | 10 |
| prepreg | | | | | | | | | |
| Involving foreign | 0 | 0 | 0 | 0 | 24 | 32 | 25 | 0 | 38 |
| substances in a roll | | | | | | | | | |
| Defect of | 0 | 0 | 0 | 0 | 2 | 4 | 5 | 12 | 0 |
| embedding | | | | | | | | | |
| Voids after curing | 0 | 0 | 0 | 0 | 3 | 6 | 6 | 100 | 0 |
| Yield | 100% | 100% | 100% | 100% | 3% | 7% | 5% | 0% | 58% |
| Operation time | ◯ | ◯ | ◯ | ◯ | Δ | Δ | Δ | ◯ | X |

Table 1 shows that in the case of laminating each prepreg with the supporting base film in the form of a roll in Examples 1 to 4 by means of the Vacuum & pressure laminator, the yield was high and productivity was high. The workability decreased due to curling of the prepreg with the supporting base film after the prepreg with the supporting base film was layered on the circuit board and thereby, the yield decreased in Comparative examples 1 to 3 using the prepreg with the supporting base film in the form of a sheet, in Comparative example 4 laminating the prepreg with the supporting base film by means of the roll laminator under ordinary pressure, and in Comparative example 5 laminating the prepreg with the supporting base film in the form of a sheet by means of the vacuum press.

1. A method for laminating a prepreg on a circuit board comprising the steps of:
1) preparing a prepreg roll selected from any of the following a) to c):
a) a prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the second resin layer side being disposed inside;
b) a prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the first resin layer side being disposed inside; and
c) a prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein the prepreg with the supporting base film is rolled up into a roll, the second resin layer side being disposed inside;
2) unreeling the prepreg with the supporting base film from the prepreg roll, peeling off the peelable film if the second resin layer is covered with the peelable film, and layering the prepreg with the supporting base film on a circuit board so that the second resin layer side of the prepreg with the supporting base film faces a circuit of the circuit board;
3) vacuum laminating the prepreg with the supporting base film on the circuit board by hot press from a supporting base film side of the prepreg with the supporting base film through a heat-resisting rubber; and
4) smoothing a surface of the first resin layer contacting the supporting base film by hot press from the supporting base film side of the prepreg with the supporting base film by means of a metal plate for press and/or metal roll for laminate.

2. The method for laminating the prepreg according to claim 1 further comprising after the step 4) of smoothing process:
5) sandwiching the circuit board having the prepreg with the supporting base film vacuum laminated between two SUS plates followed by curing at a temperature from 160 to 240° C. under ordinary pressure for 0.5 to 3 hours.

3. The method for laminating the prepreg according to claim 1, wherein a thickness of the first resin layer is in the range from 0.5 to 20 μm, and a thickness of the second resin layer is in the range from 4 to 50 μm.

4. A method for producing a printed wiring board, wherein an insulating layer on the printed wiring board is formed by the method for laminating a prepreg defined by any of claims 1 to 3.

5. A prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the second resin layer side being disposed inside.

6. A prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein a second resin layer side of the prepreg is covered with a peelable film, and the prepreg with the supporting base film is rolled up into a roll, the first resin layer side being disposed inside.

7. A prepreg roll comprising a prepreg comprising a core layer having a continuous sheet-like base material, a first resin layer formed on one surface of the core layer and a second resin layer, being thicker than the first resin layer, formed on the other surface of the core layer, and a supporting base film selected from a peelable film and a metal foil covering a first resin layer side of the prepreg, wherein the prepreg with the supporting base film is rolled up into a roll, the second resin layer side being disposed inside.
